(19) United States
(12) Patent Application Publication
(10) Pub. No.: US 2025/0038153 A1
(43) Pub. Date: Jan. 30, 2025

(54) ANCHORED LIGHT MIXING STRUCTURES IN LED PACKAGES AND RELATED METHODS

(71) Applicant: CreeLED, Inc., Durham, NC (US)

(72) Inventors: Joseph M. Favale, Jr., Cary, NC (US); Christopher P. Hussell, Raleigh, NC (US); Kevin Haberern, Cary, NC (US); Robert David Schmidt, Wake Forest, NC (US)

(21) Appl. No.: 18/508,373

(22) Filed: Nov. 14, 2023

Related U.S. Application Data
(60) Provisional application No. 63/515,266, filed on Jul. 24, 2023.

(51) Int. Cl. H01L 25/075; H01L 33/48; H01L 33/54; H01L 33/62

(52) U.S. Cl. CPC H01L 25/0753; H01L 33/486; H01L 33/54; H01L 33/62

(57) ABSTRACT

Light-emitting diode (LED) packages and more particularly anchored light mixing structures in LED packages and related methods are disclosed. LED packages include one or more LED chips and integrated light mixing structures, such as light collectors, that are placed over the LED chips to modify far field patterns. Light mixing structures are provided within recesses of LED package housings in positions over the LED chips. Sidewalls of recesses may include alignment features with shapes configured to receive corresponding shapes of light mixing structures. Alternative configurations, alone or in combination with the sidewall alignment features, may include alignment features on top surfaces of the LED packages outside of a recess. As disclosed herein, alignment features are arranged to effectively anchor a light mixing structure in place during package assembly. Additional package structures, such as encapsulants and/or epoxies, may further hold the light mixing structures in place.

### RELATED APPLICATIONS

This application claims the benefit of provisional patent application Ser. No. 63/515,266, filed Jul. 24, 2023, the disclosure of which is hereby incorporated herein by reference in its entirety.

### FIELD OF THE DISCLOSURE

The present disclosure relates to light-emitting diode (LED) packages and more particularly to anchored light mixing structures in LED packages and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials. Photons generated by the active region are initiated in all directions.

LED packages have been developed that can provide mechanical support, electrical connections, and encapsulation for LED emitters. Lumiphoric materials, such as phosphors, may also be arranged in close proximity to LED emitters to convert portions of light emissions to different wavelengths. As LED technology continues to be developed for ever-evolving modern applications, challenges exist in keeping up with operating demands for LED packages and related elements of LED packages.

LED packages that contain more than one LED chip, particularly LED packages with different colored LED chips can have far field patterns (FFPs) that have different color intensities depending on the angle at which the LED package is viewed. This is detrimental to the color uniformity of LED displays and other applications as the color is observed to change with viewing angle.

The art continues to seek improved LEDs and solid-state lighting devices having desirable illumination characteristics capable of overcoming challenges associated with conventional lighting devices.

### SUMMARY

The present disclosure relates to light-emitting diode (LED) packages and more particularly to anchored light mixing structures in LED packages and related methods. LED packages include one or more LED chips and integrated light mixing structures, such as light collectors, that are placed over the LED chips to modify far field patterns. Such light collectors may be particularly effective at mixing multiple emission point sources from multiple LED chips to approximate a single point source, or reduced-area source, with improved far field pattern uniformity. Light mixing structures are provided within recesses of LED package housings in positions over the LED chips. Sidewalls of recesses may include alignment features with shapes configured to receive corresponding shapes of light mixing structures. Alternative configurations, alone or in combination with the sidewall alignment features, may include alignment features on top surfaces of the LED packages outside of a recess. As disclosed herein, alignment features are arranged to effectively anchor a light mixing structure in place during package assembly. Additional package structures, such as encapsulants and/or epoxies, may further hold the light mixing structures in place.

In one aspect, an LED package comprises: one or more LED chips; a light collector arranged over the one or more LED chips; and at least one alignment feature configured to receive a portion of the light collector. The LED package may further comprise a housing, wherein the housing forms a recess with a recess floor and one or more recess sidewalls, and wherein the at least one alignment feature is formed in the one or more recess sidewalls. In certain embodiments, the at least one alignment feature comprises one or more of a notch, an indentation, a bore hole, a channel, a groove, and a dot in the one or more recess sidewalls. In certain embodiments, the at least one alignment feature comprises a horizontal lip parallel to the recess floor and along the one or more recess sidewalls. In certain embodiments, a ratio of a lateral dimension of the at least one alignment feature parallel to the recess floor to a distance from an outer wall of the housing to an edge of the at least one alignment feature closest to the one or more LED chips is less than 0.6. The LED package may further comprise an adhesion feature within the horizontal lip. In certain embodiments: a ratio of a lateral dimension of the at least one alignment feature parallel to the recess floor to a distance from an outer wall of the housing to an edge of the at least one alignment feature closest to the one or more LED chips is less than 0.6; and a ratio of the lateral dimension of the at least one alignment feature to a lateral dimension of the adhesion feature in a direction parallel to the recess floor is less than 0.5. In certain embodiments, the at least one alignment feature and the adhesion feature continuously extend around an entire perimeter of the recess. The LED package may further comprise a segmented adhesion feature within the horizontal lip. In certain embodiments, at least one alignment feature comprises a cutout shape in the one or more recess sidewalls, the cutout shape configured to receive a corresponding protrusion of the light collector. The LED package may further comprise an adhesion feature within the cutout shape. In certain embodiments, the at least one alignment feature comprises two alignment features on opposing sides of the one or more LED chips. The LED package may further comprise a lead frame structure at least partially within the housing, wherein the one or more LED chips are electrically coupled to one or more anode leads and one or more cathode leads of the lead frame structure In certain embodiments, portions of the one or more anode leads and portions of the one or more cathode leads extend out of the housing and bend along a bottom surface of the housing. The LED package may further comprise an underfill material on the recess floor and adjacent to the one or more LED chips. The LED package may further comprise: a first encapsulant layer on the underfill material, wherein the first encapsulant layer is between the light collector and the underfill material; and a second encapsulant layer on the light collector, wherein the light collector is between the first encapsulant layer and the second encapsulant layer. The LED package may further comprise a lens, wherein the light collector is between the lens and the one or more LED chips.

In another aspect, a method for making an LED package comprises: mounting one or more LED chips within a recess of a housing, the recess comprising a recess floor and one or more recess sidewalls with one or more alignment features; providing a first encapsulant within the recess and on the one or more LED chips; positioning a light collector on the first encapsulant such that portions of the light collector are received by the one or more alignment features; and providing a second encapsulant within the recess and on the light collector. The method may further comprise at least partially curing the first encapsulant after providing the light collector and before providing the second encapsulant. The method may further comprise curing the second encapsulant. In certain embodiments, the second encapsulant comprises at least one of a light-reflective material and a light-absorbing material. In certain embodiments, the first encapsulant is provided within the recess and at least up to the one or more alignment features. In certain embodiments, the one or more alignment features comprise one or more of a notch, an indentation, a bore hole, a channel, a groove, and a dot in the one or more recess sidewalls. In certain embodiments, the one or more alignment features comprise a horizontal lip parallel to the recess floor and along the one or more recess sidewalls. The method may further comprise an adhesion feature within the horizontal lip. In certain embodiments, the adhesion feature is segmented within the horizontal lip. In certain embodiments, the one or more alignment features and the adhesion feature continuously extend around an entire perimeter of the recess. In certain embodiments, the one or more alignment features comprise a cutout shape in the one or more recess sidewalls, the cutout shape configured to receive a corresponding protrusion of the light collector. The method may further comprise providing an underfill material within the recess before providing the first encapsulant.

In another aspect, an LED display comprises: a display panel; and at least one LED package comprising: one or more LED chips; a light collector arranged over the one or more LED chips; and at least one alignment feature configured to receive a portion of the light collector.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of a light-emitting diode (LED) package with multiple LED chips.

FIG. 1B is a top perspective view of the LED package of FIG. 1A with the LED chips omitted for illustrative purposes.

FIG. 1C is a top view of the LED package of FIG. 1A with a light collector positioned over the LED chips.

FIG. 1D is a top perspective view of the LED package of FIG. 1C.

FIG. 1E is a cross-section of the LED package of FIG. 1C taken along the line A-A of FIG. 1C.

FIG. 1F is a cross-section of the LED package of FIG. 1C taken along the line B-B of FIG. 1C.

FIG. 2A is a top view of another LED package with multiple LED chips according to principles of the present disclosure.

FIG. 2B is a top perspective view of the LED package of FIG. 2A with the LED chips omitted for illustrative purposes.

FIG. 2C is a top view of the LED package of FIG. 2A with the light collector positioned over the LED chips of FIG. 2A.

FIG. 2D is a top perspective view of the LED package of FIG. 2C.

FIG. 2E is a cross-section of the LED package of FIG. 2C taken along the line A-A of FIG. 2C.

FIG. 2F is a cross-section of the LED package of FIG. 2C taken along the line B-B of FIG. 2C.

FIG. 3A is a top view of another LED package with multiple LED chips according to principles of the present disclosure.

FIG. 3B is a top perspective view of the LED package of FIG. 3A with the LED chips omitted for illustrative purposes.

FIG. 3C is a top view of the LED package of FIG. 3A with the light collector positioned over the LED chips of FIG. 3A.

FIG. 3D is a top perspective view of the LED package of FIG. 3C.

FIG. 3E is a cross-section of the LED package of FIG. 3C taken along the line A-A of FIG. 3C.

FIG. 3F is a cross-section of the LED package of FIG. 3C taken along the line B-B of FIG. 3C.

FIG. 4A is a top view of another LED package with multiple LED chips according to principles of the present disclosure.

FIG. 4B is a top perspective view of the LED package of FIG. 4A with the LED chips omitted for illustrative purposes.

FIG. 4C is a top view of the LED package of FIG. 4A with the light collector positioned over the LED chips of FIG. 4A.

FIG. 4D is a top perspective view of the LED package of FIG. 4C.

FIG. 4E is a cross-section of the LED package of FIG. 4C taken along the line A-A of FIG. 4C.

FIG. 4F is a cross-section of the LED package of FIG. 4C taken along the line B-B of FIG. 4C.

FIG. 5A is a top view of another LED package with multiple LED chips according to principles of the present disclosure.

FIG. 5B is a top perspective view of the LED package of FIG. 5A with the LED chips omitted for illustrative purposes.

FIG. 5C is a top view of the LED package of FIG. 5A with the light collector positioned over the LED chips of FIG. 5A.

FIG. 5D is a top perspective view of the LED package of FIG. 5C.

FIG. 5E is a cross-section of the LED package of FIG. 5C taken along the line A-A of FIG. 5C.

FIG. 5F is a cross-section of the LED package of FIG. 5C taken along the line B-B of FIG. 5C.

FIG. 6A is a top view of another LED package with multiple LED chips according to principles of the present disclosure.

FIG. 6B is a top perspective view of the LED package of FIG. 6A with the LED chips omitted for illustrative purposes.

FIG. 6C is a top view of the LED package of FIG. 6A with the light collector positioned over the LED chips of FIG. 6A.

FIG. 6D is a top perspective view of the LED package of FIG. 6C.

FIG. 6E is a cross-section of the LED package of FIG. 6C taken along the line A-A of FIG. 6C.

FIG. 6F is a cross-section of the LED package of FIG. 6C taken along the line B-B of FIG. 6C.

FIG. 7A is a top view of another LED package with multiple LED chips according to principles of the present disclosure.

FIG. 7B is a cross-section of the LED package of FIG. 7A taken along the line A-A of FIG. 7A.

FIG. 7C is a cross-section of the LED package of FIG. 7A taken along the line B-B of FIG. 7A.

FIG. 8A is a top view of another LED package with multiple LED chips according to principles of the present disclosure.

FIG. 8B is a top perspective view of the LED package of FIG. 8A with the LED chips omitted for illustrative purposes.

FIG. 8C is a top view of the LED package of FIG. 8A with the light collector positioned over the LED chips of FIG. 8A.

FIG. 8D is a top perspective view of the LED package of FIG. 8C.

FIG. 8E is a cross-section of the LED package of FIG. 8C taken along the line A-A of FIG. 8C.

FIG. 8F is a cross-section of the LED package of FIG. 8C taken along the line B-B of FIG. 8C.

FIG. 9A is a top view of another LED package with multiple LED chips according to principles of the present disclosure.

FIG. 9B is a top perspective view of the LED package of FIG. 9A with the LED chips omitted for illustrative purposes.

FIG. 9C is a top view of the LED package of FIG. 9A with the light collector positioned over the LED chips of FIG. 9A.

FIG. 9D is a top perspective view of the LED package of FIG. 9C.

FIG. 9E is a cross-section of the LED package of FIG. 9C taken along the line A-A of FIG. 9C.

FIG. 9F is a cross-section of the LED package of FIG. 9C taken along the line B-B of FIG. 9C.

FIG. 10A is a top view of another LED package with multiple LED chips according to principles of the present disclosure.

FIG. 10B is a top perspective view of the LED package of FIG. 10A with the LED chips omitted for illustrative purposes.

FIG. 10C is a top view of the LED package of FIG. 10A with the light collector positioned over the LED chips of FIG. 10A.

FIG. 10D is a top perspective view of the LED package of FIG. 10C.

FIG. 10E is a cross-section of the LED package of FIG. 10C taken along the line A-A of FIG. 10C.

FIG. 10F is a cross-section of the LED package of FIG. 10C taken along the line B-B of FIG. 10C.

FIG. 11A is a top view of another LED package with multiple LED chips according to principles of the present disclosure.

FIG. 11B is a top perspective view of the LED package of FIG. 11A with the LED chips omitted for illustrative purposes.

FIG. 11C is a top view of the LED package of FIG. 11A with the light collector positioned over the LED chips of FIG. 11A.

FIG. 11D is a top perspective view of the LED package of FIG. 11C.

FIG. 11E is a cross-section of the LED package of FIG. 11C taken along the line A-A of FIG. 11C.

FIG. 11F is a cross-section of the LED package of FIG. 11C taken along the line B-B of FIG. 11C.

FIG. 12 is a cross-section of an LED package that is similar to the LED package of FIGS. 1A to 1F with one or more encapsulants formed within the recess.

FIG. 13 is a cross-section of an LED package that is similar to the LED package of FIG. 12 for embodiments where the alignment features form bore holes in the housing.

FIG. 14 illustrates top views of various shapes for alignment features according to principles of the present disclosure.

FIG. 15 is a top view of an LED package that is similar to the LED package of FIGS. 1A to 1F for embodiments where the alignment features are provided on opposing sidewalls of the recess.

FIG. 16 is a top view of an LED package that is similar to the LED package of FIG. 15 for embodiments where the alignment features and the protrusions of the light collector have different shapes.

FIG. 17 is a top view of an LED package that is similar to the LED package of FIG. 16 for embodiments where the alignment features and the protrusions of the light collector also have different shapes.

FIG. 18 is a top view of an LED package that is similar to the LED package of FIG. 15 for embodiments where the alignment features are formed with circular shapes or dots as described above for FIG. 14.

FIG. 19 is a schematic process flow representing a method of manufacturing LED packages according to principles of the present disclosure.

FIG. 20 is a cross-section of an LED package that is similar to the LED package of FIG. 12 with the addition of a lens.

FIG. 21 is a schematic diagram of a portion of an LED display screen comprising a large number of LED packages from any of FIGS. 1A-20.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) packages and more particularly to anchored light mixing structures in LED packages and related methods. LED packages include one or more LED chips and integrated light mixing structures, such as light collectors, that are placed over the LED chips to modify far field patterns (FFPs). Such light collectors may be particularly effective at mixing multiple emission point sources from multiple LED chips to approximate a single point source, or reduced-area source, with improved FFP uniformity. Light mixing structures are provided within recesses of LED package housings in positions over the LED chips. Sidewalls of recesses may include alignment features with shapes configured to receive corresponding shapes of light mixing structures. Alternative configurations, alone or in combination with the sidewall alignment features, may include alignment features on top surfaces of the LED packages outside of a recess. As disclosed herein, alignment features are arranged to effectively anchor a light mixing structure in place during package assembly. Additional package structures, such as encapsulants and/or epoxies, may further hold the light mixing structures in place.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (AI), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds.

The active LED structure may be grown on a growth substrate that can include many materials, such as sapphire, SiC, silicon, aluminum nitride (AlN), and GaN. Sapphire is common substrate for Group III nitrides and also has certain advantages, including being lower cost, having established manufacturing processes, and having good light-transmissive optical properties, among other related substrates.

Different embodiments of the active LED structure can emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{1-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support member, such as a submount or a lead frame. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. In still further embodiments, the support structure may embody a lead frame structure. Light-altering materials may be arranged within LED packages to reflect or otherwise redirect light from the one or more LED chips in a desired emission direction or pattern.

In certain embodiments, aspects of the present disclosure relate LED packages with lead frame structures that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The body may be formed on the lead frame structure before singulation so that the individual lead frame portions may be electrically isolated from one another and mechanically supported by the body within an individual LED package. The body may form a cup or a recess in which one or more LED chips may be mounted to the lead frame at a floor of the recess. Portions of the lead frame structure may extend from the recess and through the body to protrude or be accessible outside of the body to provide external electrical connections. An encapsulant material, such as silicone or epoxy, may fill the recess to encapsulate the one or more LED chips.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

As described above, an exemplary LED package may include one or more LED chips and an integrated light mixing structure, such as a light collector. The light collector is positioned internal to the LED package and over the LED chips to modify far field patterns (FFPs). For multiple emission color embodiments, such as red, green, and blue LED chips, the light collector may be effectively mixing multiple emission point sources from the multiple LED chips to approximate a single point source from the LED package. The light collector may be anchored and/or fixed within the package by alignment features that are integrated within the housing.

Alignment features may include various shapes, such as notches, indentations, bore holes, channels, grooves, and dots among other features, with shapes that correspond to portions of the light collector. Alignment features may comprise round, squared, and keyed cutout shapes, among others, along the package housing. Alignment features may be spaced apart in a discontinuous manner along portions of a package housing. In other embodiments, one or more alignment features may be arranged in a continuous manner along the package housing, including around an entire perimeter of a package recess. Package recesses may include various shapes, such as round upper openings with rectelliptical recess floors where lead frames are exposed. During package assembly, the light collector may be positioned within the housing to lock in place by way of the alignment features. Such alignment features may allow hands-free placement of light collectors, such as by way of shaker tables.

Alignment features as disclosed herein may be formed in portions of package housing by various techniques, including custom injection molding, laser engraving, and etched injection molding with texture that can still release. In certain embodiments, alignment features are formed and after housings are molded by one or more of etching, grinding, cutting, and/or grooving.

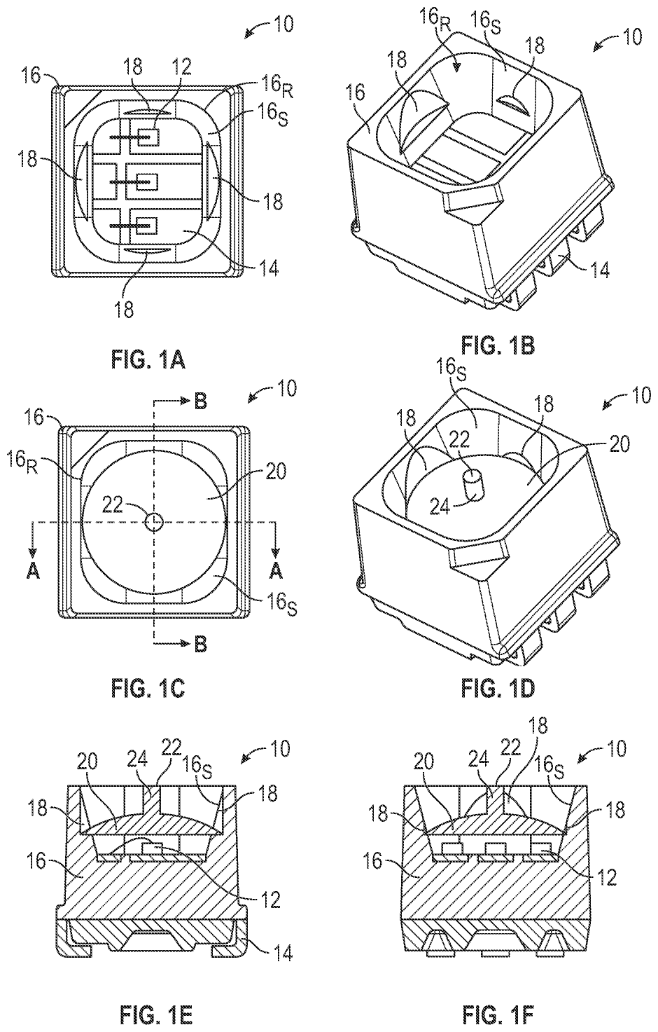

FIG. 1A is a top view of an LED package 10 with multiple LED chips 12 according to principles of the present disclosure. FIG. 1B is a top perspective view of the LED package 10 of FIG. 1A with the LED chips 12 omitted for illustrative purposes. The LED chips 12 may be configured to all emit a same emission color or the LED chips 12 may be configured to emit different emission colors, such as red, green, and blue wavelengths. The LED package 10 is a lead frame package that includes a lead frame structure 14 within a housing 16. The LED chips 12 are within a recess 16_{R} of the housing 16 and are mounted and/or electrically coupled to portions of the lead frame structure 14 exposed at a bottom of the recess 16_{R}. In FIG. 1A, each LED chip 12 is mounted and electrically coupled to a lead of the lead frame structure 14 and electrically coupled to a corresponding lead by way of a wire bond. However, other electrical connections are possible, such as lateral LED chip structures where two wire bonds are coupled to opposing leads or flip-chip structures that do not require wire bonds. In this manner, each LED chip 12 is electrically coupled to an anode lead and a corresponding cathode lead of the lead frame structure 14. As illustrated in FIG. 1A, sidewalls 16s of the recess 16_{R} include one or more alignment features 18. By way of example, four alignment features 18 are provided, one on each of the opposing sidewalls 16s. The alignment features 18 may be formed as notches or indentations of the housing 16. As best illustrated in FIG. 1B, the alignment features 18 form rounded cutout portions of the sidewalls 16s with a lip at a base of the alignment feature 18.

FIG. 1C is a top view of the LED package 10 of FIG. 1A with a light collector 20 positioned over the LED chips 12 of FIG. 1A. FIG. 1D is a top perspective view of the LED package 10 of FIG. 1C. As illustrated, the light collector 20 is positioned within the recess 16_{R} and along the sidewalls 16_{S}. Portions of the light collector 20 fit along the alignment features 18 to effectively anchor the light collector 20 in place. For example, the light collector 20 may fit within the rounded cutout portions and on the lips of the alignment features 18 as illustrated in FIG. 1B. Depending on the embodiment, the light collector 20 may have many different shapes. In FIGS. 1C and 1D, the light collector 20 includes an aperture 22 and a stem portion 24.

In certain embodiments, the light collector 20 may be formed from epoxy, silicone, or some other light-transmissive material. The light collector 20 may be coated with a reflective coating on a top surface thereof except for the aperture 22 at or near the apex, center, or top of the light collector 20. The light collector 20 may comprise a reflective material through the light collector 20. For example, the light collector 20 may embody a white material. Light emitted by the LED chips 12 enters the light collector 20 and may reflect one or more times, thereby mixing within the light collector 20 before eventually exiting via the aperture 22. The light mixing within the light collector 20 before exiting via the aperture 22 results in light from each of the LED chips 12 appearing as if the light originated from a single emission point or area (i.e., the aperture 22) instead of from three separate and distinct locations of the LED chips 12. Accordingly, the emission pattern and color over angle shifts of light may be improved. It is to be appreciated that when the present disclosure refers to a single emission point, this is not a point in a mathematical sense, but instead refers to a single emission source (e.g., an LED chip or the output of the plurality of LED chips from the aperture 22). In this sense, a point can be a term for a light source that is smaller than the LED package 10 or system being described, and the size can depend on the overall system.

In certain embodiments, the light collector 20 is configured to receive light from the LED chips 12 and the stem portion 24 may have the shape of a cylinder that protrudes from a top, center, or apex of the light collector 20. In other embodiments, the stem portion 24 may have a shape other than being cylindrical. A height of the stem portion 24 can be such that it reduces or avoids a direct line of sight from the LED chip 12. In other embodiments, the light collector 20 may be formed without the stem portion 24.

FIG. 1E is a cross-section of the LED package of FIG. 1C taken along the line A-A of FIG. 1C. FIG. 1F is a cross-section of the LED package of FIG. 1C taken along the line B-B of FIG. 1C. As illustrated, the position of the alignment features 18 is configured to place the light collector 20 at a predetermined distance above the LED chips 12. The alignment features 18 may include horizontal lip portions where the light collector 20 fits into place. In certain embodiments, portions of the leads (e.g., anode leads and/or cathode leads) extend out of the housing 16 and bend along a bottom surface of the housing 16. Such a configuration may form a useful geometry or form factor for outdoor applications.

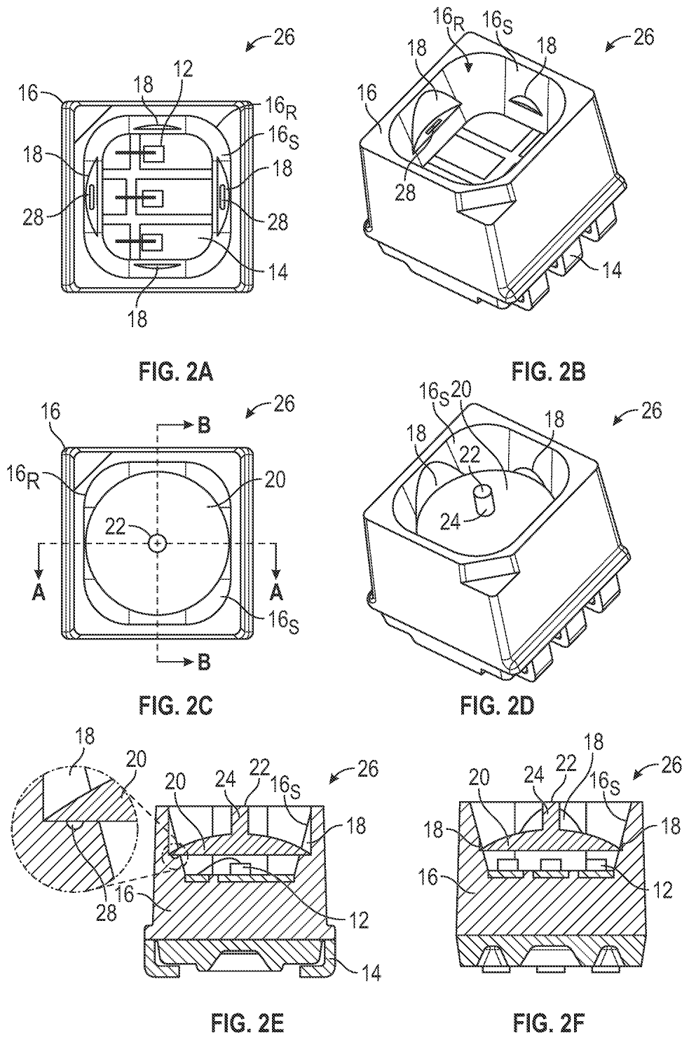

FIG. 2A is a top view of another LED package 26 with multiple LED chips 12 according to principles of the present disclosure. The LED package 26 is similar to the LED package 10 of FIGS. 1A to 1F and further includes an adhesion feature 28 in one or more of the alignment features 18. FIG. 2B is a top perspective view of the LED package 26 of FIG. 2A with the LED chips 12 omitted for illustrative purposes. FIG. 2C is a top view of the LED package 26 of FIG. 2A with the light collector 20 positioned over the LED chips 12 of FIG. 2A. FIG. 2D is a top perspective view of the LED package 26 of FIG. 2C. FIG. 2E is a cross-section of the LED package 26 of FIG. 2C taken along the line A-A of FIG. 2C. FIG. 2F is a cross-section of the LED package 26 of FIG. 2C taken along the line B-B of FIG. 2C. The adhesion feature 28 may be integrated with one or more of the alignment features 18 to promote improved adhesion in the final package. The adhesion feature 28 may comprise one or more of a groove, channel, dot, indentation, or texture within one or more of the alignment features 18. As best illustrated in FIG. 2E, in certain embodiments, the adhesion feature 28 may be formed as a downward groove or trench with a rounded bottom in the lip of the alignment feature 18. In this manner, when an encapsulant material, such as silicone or epoxy, is filled into the recess 16_{R}, portions of the encapsulant may fill the adhesion feature 28 to better adhere the light collector 20 in place.

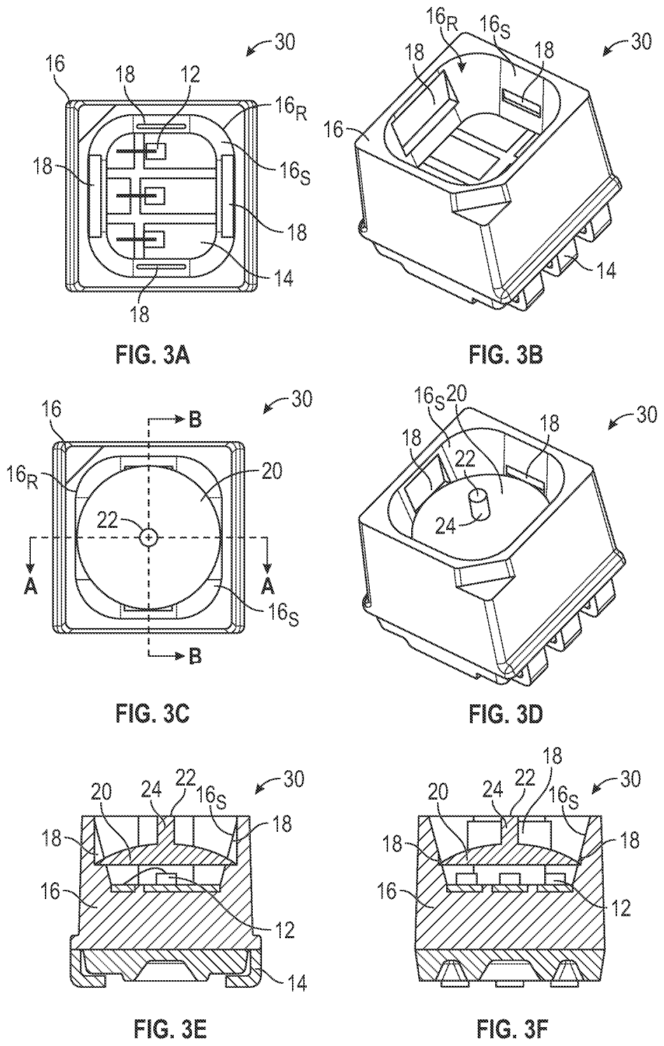

FIG. 3A is a top view of another LED package 30 with multiple LED chips 12 according to principles of the present disclosure. The LED package 30 is similar to the LED package 10 of FIGS. 1A to 1F for embodiments where a top of the recess 16_{R} forms a squared and/or rectelliptical shape. FIG. 3B is a top perspective view of the LED package 30 of FIG. 3A with the LED chips 12 omitted for illustrative purposes. FIG. 3C is a top view of the LED package 30 of FIG. 3A with the light collector 20 positioned over the LED chips 12 of FIG. 3A. FIG. 3D is a top perspective view of the LED package 30 of FIG. 3C. FIG. 3E is a cross-section of the LED package 30 of FIG. 3C taken along the line A-A of FIG. 3C. FIG. 3F is a cross-section of the LED package 30 of FIG. 3C taken along the line B-B of FIG. 3C.

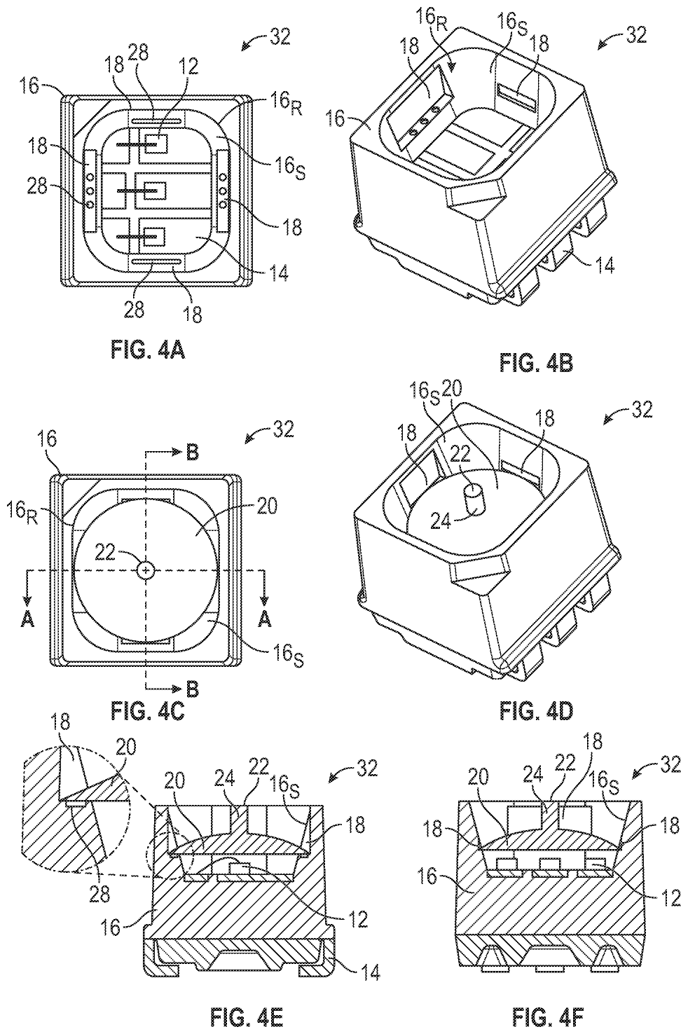

FIG. 4A is a top view of another LED package 32 with multiple LED chips 12 according to principles of the present disclosure. The LED package 32 is similar to the LED package 26 of FIGS. 2A to 2F for embodiments where the adhesion features 28 have squared bottoms and/or are segmented in certain alignment features 18. FIG. 4B is a top perspective view of the LED package 32 of FIG. 4A with the LED chips 12 omitted for illustrative purposes. FIG. 4C is a top view of the LED package 32 of FIG. 4A with the light collector 20 positioned over the LED chips 12 of FIG. 4A. FIG. 4D is a top perspective view of the LED package 32 of FIG. 4C. FIG. 4E is a cross-section of the LED package 32 of FIG. 4C taken along the line A-A of FIG. 4C. FIG. 4F is a cross-section of the LED package 32 of FIG. 4C taken along the line B-B of FIG. 4C. The adhesion feature 28 may be integrated with one or more of the alignment features 18 to promote improved adhesion in the final package. As illustrated in FIG. 4A, adhesion features 28 may extend continuously along certain alignment features or in a discontinuous or segmented manner. For example, the alignment features 18 of the left and right sidewalls 16_{R} include segmented adhesion features 28 that are spaced apart along the same lip to promote further adhesion while the top and bottom sidewalls 16_{R} have continuous adhesion features 28. As best illustrated in FIG. 4E, the adhesion feature 28 may be formed as a downward groove or trench with a squared bottom in the lip of the alignment feature 18. In this manner, when an encapsulant material, such as silicone or epoxy, is filled into the recess 16_{R}, portions of the encapsulant may fill the adhesion features 28 to better adhere the light collector 20 in place.

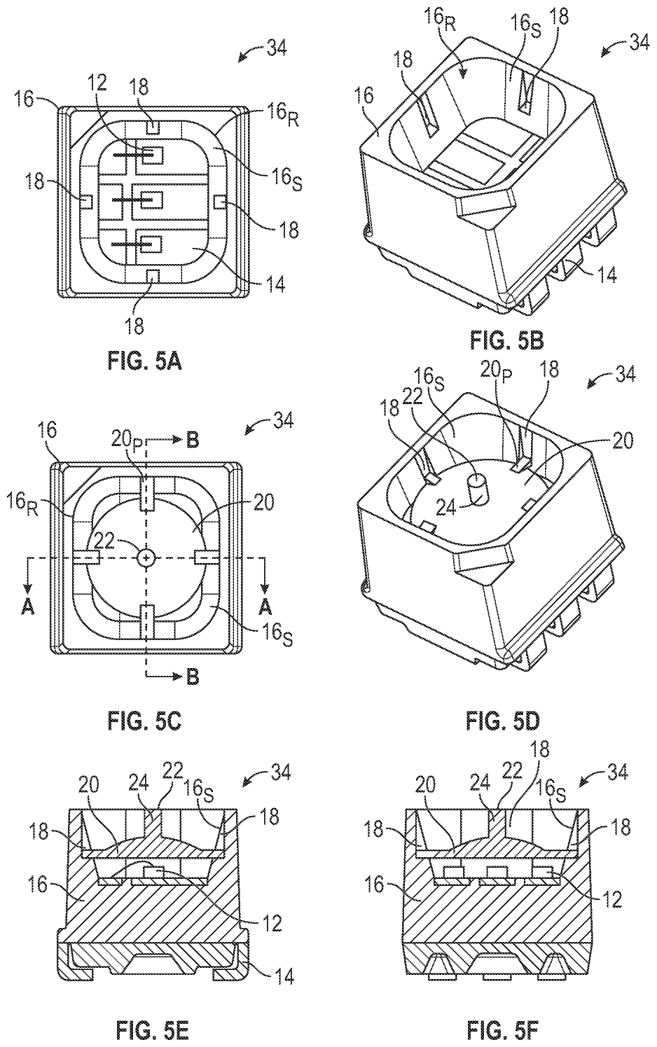

FIG. 5A is a top view of another LED package 34 with multiple LED chips 12 according to principles of the present disclosure. The LED package 34 is similar to the LED package 10 of FIGS. 1A to 1F for embodiments where the alignment features 18 form keyed cutout shapes configured to receive corresponding protrusions 20_{P} of the light collector 20. FIG. 5B is a top perspective view of the LED package 34 of FIG. 5A with the LED chips 12 omitted for illustrative purposes. FIG. 5C is a top view of the LED package 34 of FIG. 5A with the light collector 20 positioned over the LED chips 12 of FIG. 5A. FIG. 5D is a top perspective view of the LED package 34 of FIG. 5C. FIG. 5E is a cross-section of the LED package 34 of FIG. 5C taken along the line A-A of FIG. 5C. FIG. 5F is a cross-section of the LED package 34 of FIG. 5C taken along the line B-B of FIG. 5C. As illustrated, the protrusions 20_{P} of the light collector 20 fit into the keyed cutout shapes of the alignment features 18 to lock the light collector 20 in place.

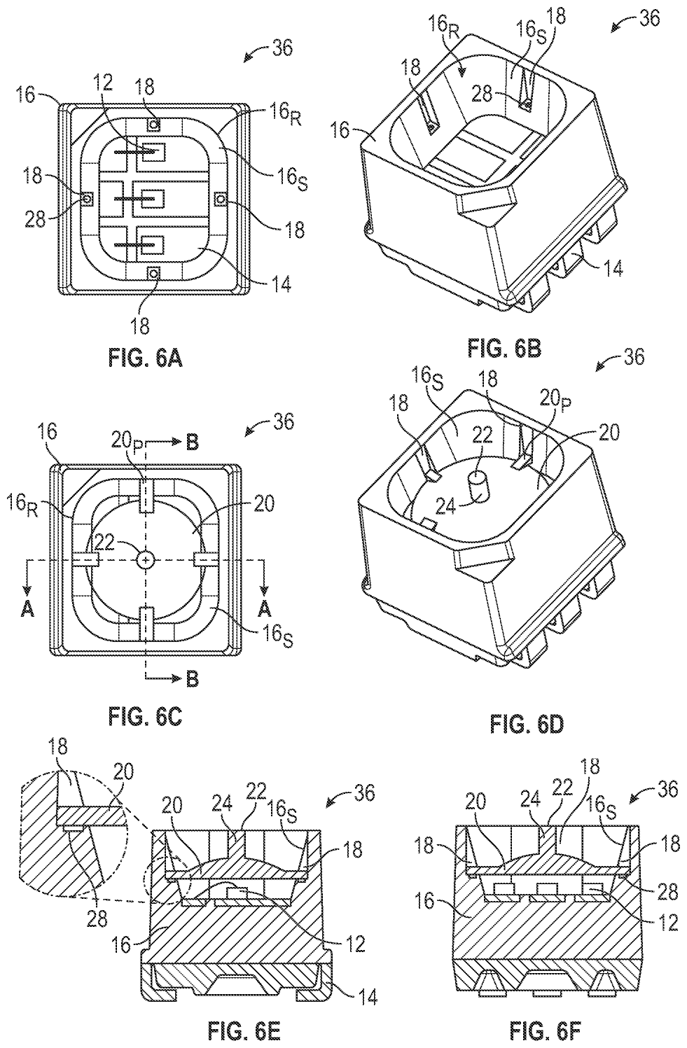

FIG. 6A is a top view of another LED package 36 with multiple LED chips 12 according to principles of the present disclosure. The LED package 36 is similar to the LED package 34 of FIGS. 5A to 5F for embodiments where the keyed cutout shapes of the alignment features 18 further include the adhesion features 28 as previously described. FIG. 6B is a top perspective view of the LED package 36 of FIG. 6A with the LED chips 12 omitted for illustrative purposes. FIG. 6C is a top view of the LED package 36 of FIG. 6A with the light collector 20 positioned over the LED chips 12 of FIG. 6A. FIG. 6D is a top perspective view of the LED package 36 of FIG. 6C. FIG. 6E is a cross-section of the LED package 36 of FIG. 6C taken along the line A-A of FIG. 6C. FIG. 6F is a cross-section of the LED package 36 of FIG. 6C taken along the line B-B of FIG. 6C. As illustrated, the protrusions 20_{P} of the light collector 20 fit into the keyed cutout shapes of the alignment features 18 to lock the light collector 20 in place in combination with the adhesion features 28.

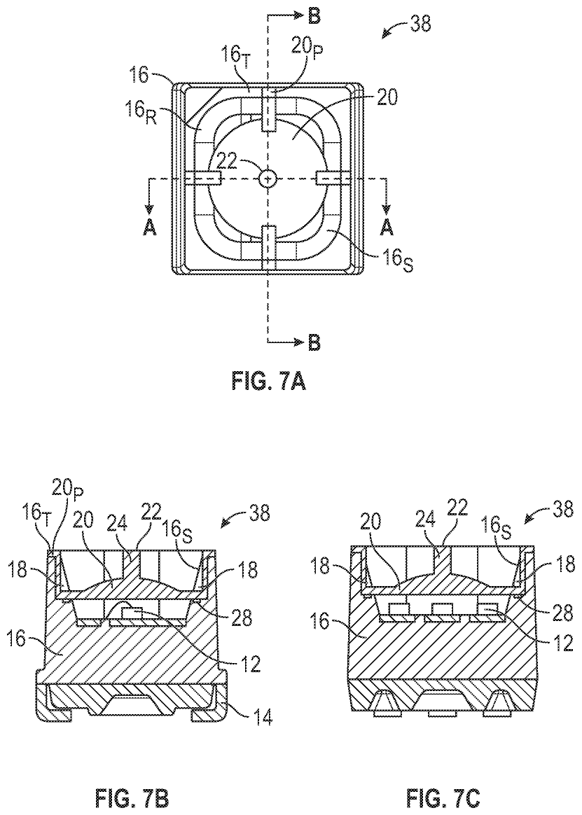

FIG. 7A is a top view of another LED package 38 with the light collector 20 positioned over multiple LED chips 12 according to principles of the present disclosure. The LED package 38 is similar to the LED package 36 of FIGS. 6A to 6F for embodiments where the keyed cutout shapes of the alignment features 18 further extend out of the recess 16_{R} and along a top surface 16_{T} of the housing 16. FIG. 7B is a cross-section of the LED package 38 of FIG. 7A taken along the line A-A of FIG. 7A. FIG. 7C is a cross-section of the LED package 38 of FIG. 7A taken along the line B-B of FIG. 7A. As illustrated, the protrusions 20_{P} of the light collector 20 fit into the keyed cutout shapes of the alignment features 18 and also extend out of the recess 16_{R} and along the top surface 16_{T} of the housing 16. In certain embodiments, the portions of the protrusions 20_{P} that extend out of the recess 16_{R} may have top surfaces that are coplanar or below the top surface 16_{T} of the housing 16.

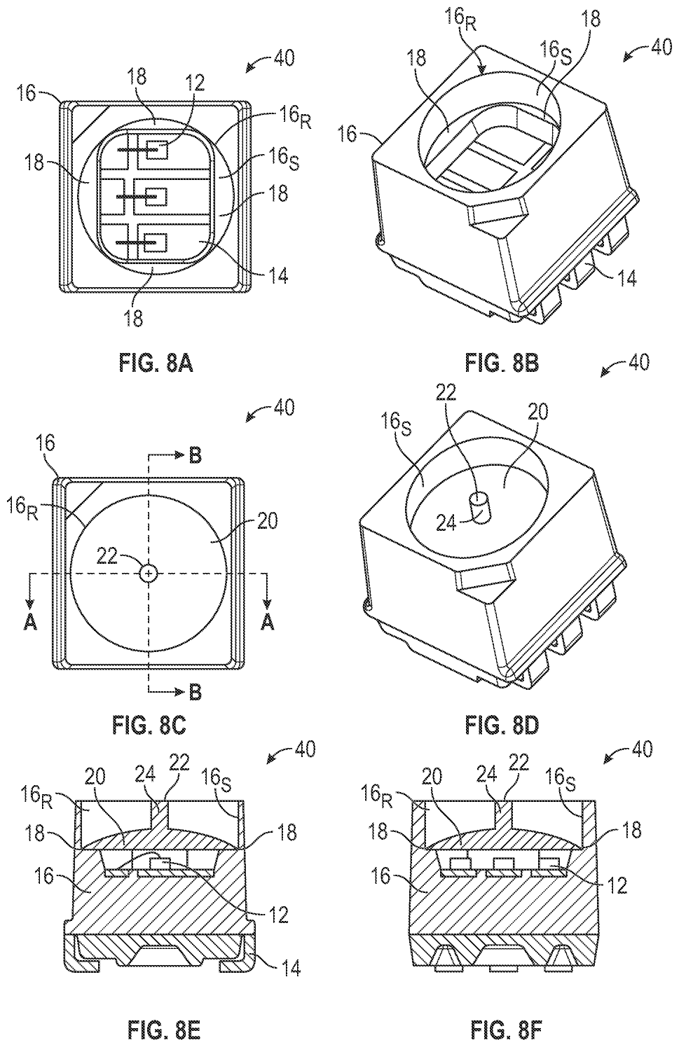

FIG. 8A is a top view of another LED package 40 with multiple LED chips 12 according to principles of the present disclosure. The LED package 40 is similar to the LED package 10 of FIGS. 1A to 1F for embodiments where the one or more alignment features 18 form curved lips along the sidewalls 16s. FIG. 8B is a top perspective view of the LED package 40 of FIG. 8A with the LED chips 12 omitted for illustrative purposes. FIG. 8C is a top view of the LED package 40 of FIG. 2A with the light collector 20 positioned over the LED chips 12 of FIG. 8A. FIG. 8D is a top perspective view of the LED package 40 of FIG. 8C. FIG. 8E is a cross-section of the LED package 40 of FIG. 8C taken along the line A-A of FIG. 8C. FIG. 8F is a cross-section of the LED package 40 of FIG. 8C taken along the line B-B of FIG. 8C. As illustrated, the top of the recess 16_{R} is rounded and a floor of the recess has a rectelliptical shape. The one or more alignment features 18 are curved around the sidewalls 16s in a manner that follows a curvature of the recess 16_{R} and one or more alignment features 18 form a horizontal lip that curves about the recess 16_{R}. When the light collector 20 is assembled, a portion of the light collector 20 rests on the lip and is then further adhered by the encapsulant and/or epoxy as previously described. As best illustrated in FIGS. 8E and 8F, portions of the sidewalls 16s that are below the light collector 20 and the alignment features 18 are also angled toward the floor of the recess 16_{R}.

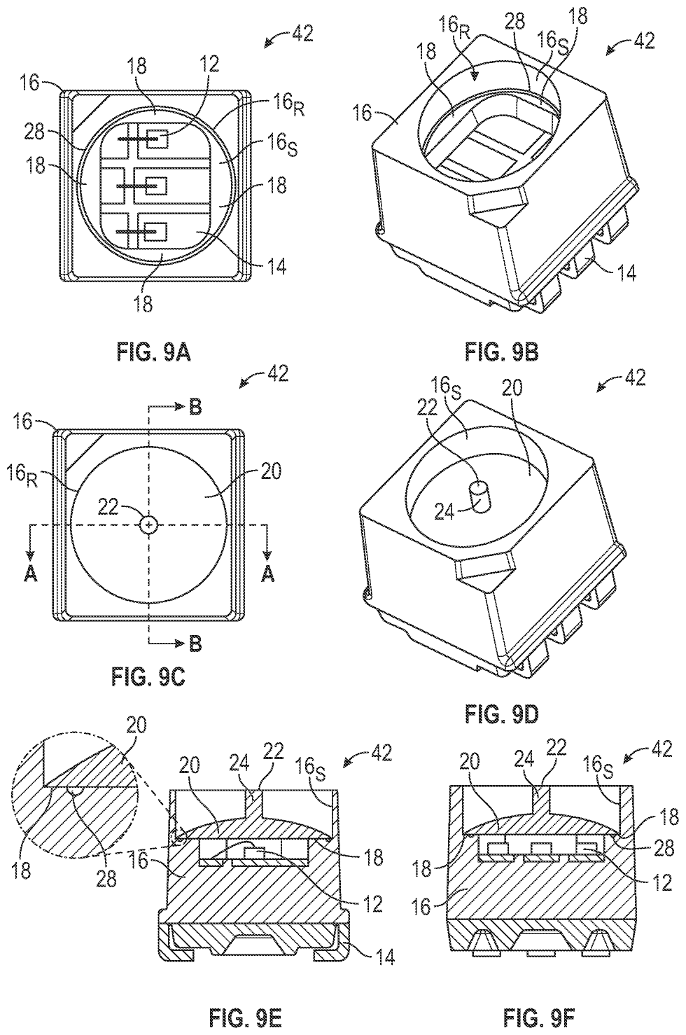

FIG. 9A is a top view of another LED package 42 with multiple LED chips 12 according to principles of the present disclosure. The LED package 42 is similar to the LED package 40 of FIGS. 8A to 8F for embodiments that further include the adhesion feature 28 formed along the curved lip of the alignment feature 18. FIG. 9B is a top perspective view of the LED package 42 of FIG. 9A with the LED chips 12 omitted for illustrative purposes. FIG. 9C is a top view of the LED package 42 of FIG. 9A with the light collector 20 positioned over the LED chips 12 of FIG. 9A. FIG. 9D is a top perspective view of the LED package 42 of FIG. 9C. FIG. 9E is a cross-section of the LED package 42 of FIG. 9C taken along the line A-A of FIG. 9C. FIG. 9F is a cross-section of the LED package 42 of FIG. 9C taken along the line B-B of FIG. 9C. For the LED package 42, the adhesion feature 28 forms a continuous groove around an entire perimeter of the recess 16_{R} and along the horizontal lip of the alignment feature 18.

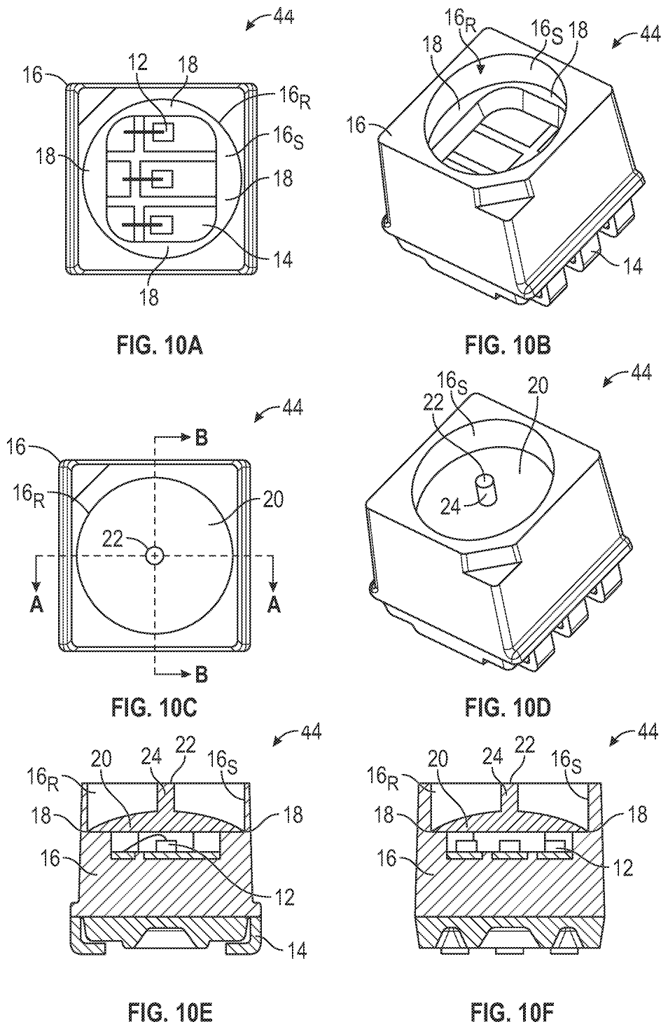

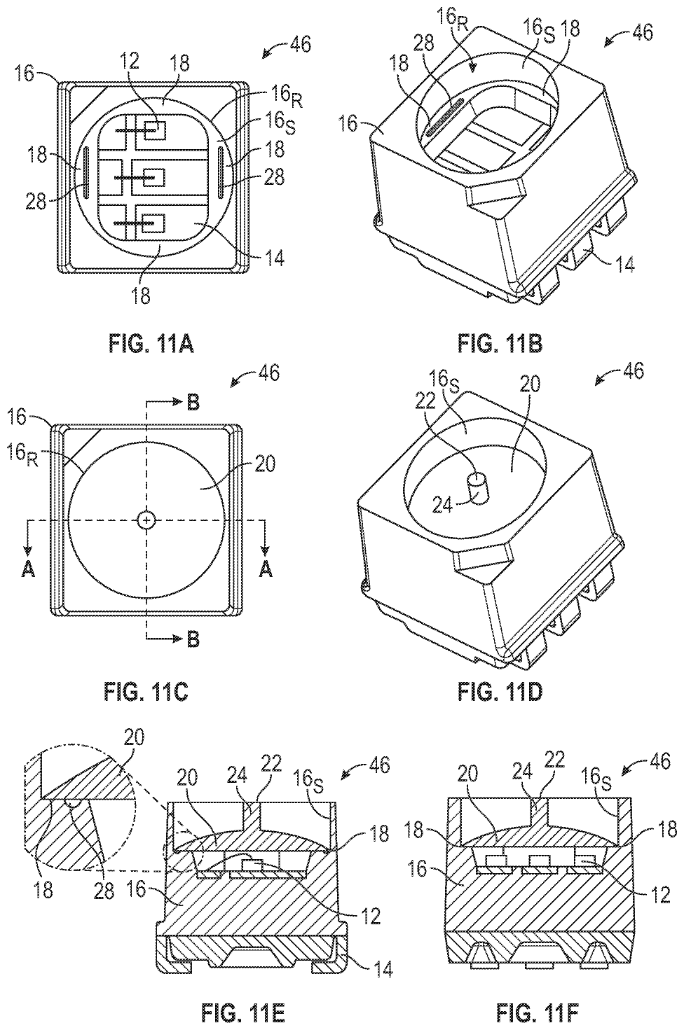

FIG. 10A is a top view of another LED package 44 with multiple LED chips 12 according to principles of the present disclosure. The LED package 44 is similar to the LED package 40 of FIGS. 8A to 8F for embodiments where portions of the sidewalls 16s that are below the light collector 20 and the alignment features 18 are perpendicular to the floor of the recess 16_{R}. FIG. 10B is a top perspective view of the LED package 44 of FIG. 10A with the LED chips 12 omitted for illustrative purposes. FIG. 10C is a top view of the LED package 44 of FIG. 10A with the light collector 20 positioned over the LED chips 12 of FIG. 10A. FIG. 10D is a top perspective view of the LED package 44 of FIG. 10C. FIG. 10E is a cross-section of the LED package 44 of FIG. 10C taken along the line A-A of FIG. 10C. FIG. 10F is a cross-section of the LED package 44 of FIG. 10C taken along the line B-B of FIG. 10C.

FIG. 11A is a top view of another LED package 46 with multiple LED chips 12 according to principles of the present disclosure. The LED package 46 is similar to the LED package 40 of FIGS. 8A to 8F for embodiments that further include several adhesion features 28 formed along the curved lip of the alignment feature 18. FIG. 11B is a top perspective view of the LED package 46 of FIG. 11A with the LED chips 12 omitted for illustrative purposes. FIG. 11C is a top view of the LED package 46 of FIG. 11A with the light collector 20 positioned over the LED chips 12 of FIG. 11A. FIG. 11D is a top perspective view of the LED package 46 of FIG. 10C. FIG. 10E is a cross-section of the LED package 46 of FIG. 11C taken along the line A-A of FIG. 11C. FIG. 11F is a cross-section of the LED package 46 of FIG. 10C taken along the line B-B of FIG. 11C.

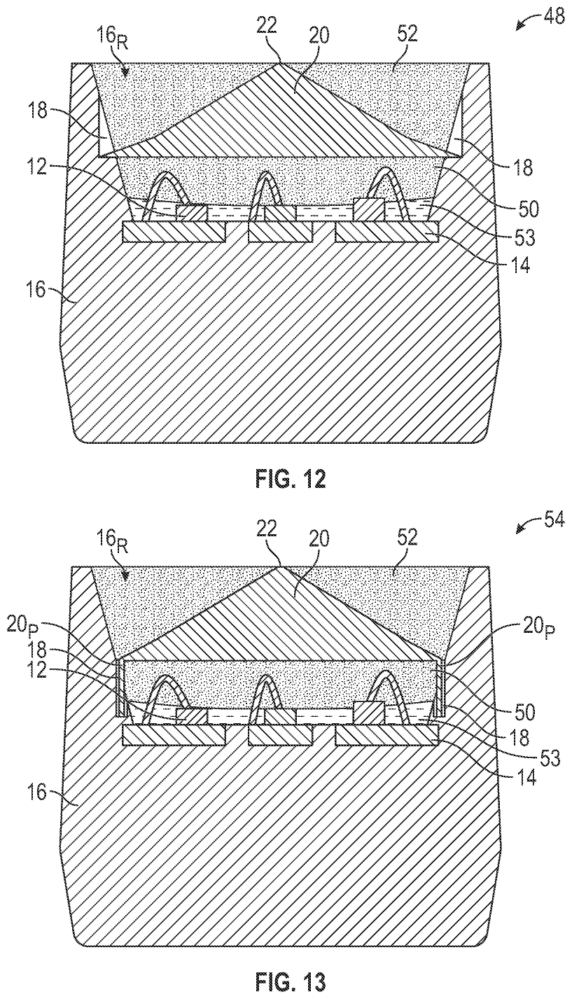

FIG. 12 is a cross-section of an LED package 48 that is similar to the LED package 10 of FIGS. 1A to 1F with one or more encapsulants 50, 52 formed within the recess 16_{R}. The alignment features 18 may include macro-texture features, such as a notch, an indentation, a channel, a groove, and a dot in the one or more recess sidewalls 16s. During assembly, the LED chips 12 may first be mounted and electrically coupled to the lead frame structure 14. Next, the first encapsulant 50 may be partially filled within the recess 16_{R} up to and sometimes over the alignment features 18. The light collector 20 may then be positioned on the first encapsulant 50 and alignment features 18. In certain embodiments, the amount of first encapsulant 50 should be enough so that when the light collector 20 is positioned on the alignment features 18, little or no air bubbles are formed. After positioning of the light collector 20, the first encapsulant 50 may be at least partially cured to anchor the light collector 20 in place. Next, the second encapsulant 52 may be filled and cured on the light collector 20 and in the recess 16_{R}. In certain embodiments, the first and second encapsulants 50, 52 comprise light-transmissive and/or light-transparent materials, such as silicone, epoxy, and polymethyl methacrylate (PMMA), among other encapsulant materials. In further embodiments, since the second encapsulant 52 is above the light collector 20, the second encapsulant 52 may include a light-reflective material for enhanced brightness or a light-absorbing material for enhanced contrast. The LED package 48 may further include a third encapsulant 53 that is between the first encapsulant 50 and the floor of the recess 16_{R}. The third encapsulant 53 may be formed after the LED chips 12 are mounted and before the first and second encapsulants 50, 52 and the light collector 20 are assembled. In certain embodiments, the third encapsulant 53 may comprise a light-altering material that is reflective to light emitted by the LED chips 12. For example, the third encapsulant 53 may comprise silicone with light-reflective and/or light-refractive particles such as titanium dioxide. In such examples, the third encapsulant 53 may have a white color for increasing light reflectivity along the floor of the recess 16_{R}. As used herein, the third encapsulant 53 may also be referred to as an underfill material.

FIG. 13 is a cross-section of an LED package 54 that is similar to the LED package 48 of FIG. 12 for embodiments where the alignment features 18 form bore holes in the housing 16. As illustrated, the alignment features 18 form holes that extend downward from the sidewalls 16s toward a bottom of the LED package 54. Protrusions 20_{P} of the light collector 20 are sized and shaped to fit within the holes to fix the light collector 20 in place. As illustrated in FIG. 13, the protrusions 20_{P} extend downward from the light collector 20 to correspond with shapes of the respective alignment features 18.

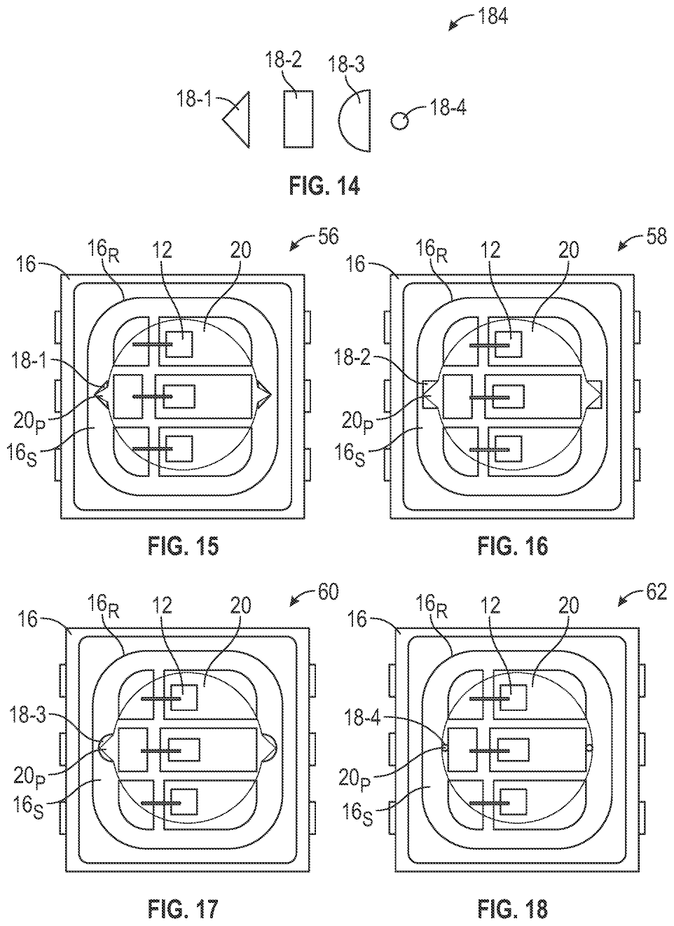

FIG. 14 illustrates top views of various shapes for alignment features 18 according to principles of the present disclosure. For example, from the top view, shapes may include triangles (i.e., 18-1), rectangles (i.e., 18-2), half circles (i.e., 18-3), and/or circles or dots (i.e., 18-4). In certain embodiments, the circles or dots may embody bore holes as described above for FIG. 13. The shapes illustrated in FIG. 14 may be provided for any of the previously described embodiments of FIGS. 1A to 13.

FIG. 15 is a top view of an LED package 56 that is similar to the LED package 10 of FIGS. 1A to 1F for embodiments where the alignment features 18-1 are provided on opposing sidewalls 16s of the recess 16_{R}. As illustrated, the alignment features 18-1 form the shape of triangles similar to FIG. 14. In a similar manner, the protrusions 20_{P} of the light collector 20 are also formed in the shape of triangles for securing the light collector 20 in place.

FIG. 16 is a top view of an LED package 58 that is similar to the LED package 56 of FIG. 15 for embodiments where the alignment features 18-2 and the protrusions 20_{P} of the light collector 20 have different shapes. As illustrated, the alignment features 18-2 form the shape of rectangles similar to FIG. 14, and the protrusions 20_{P} of the light collector 20 are formed in the shape of triangles that fit within the rectangles of the alignment features 18-2 for securing in place. By having different shapes, increased tolerances for placement of the light collector 20 may be provided.

FIG. 17 is a top view of an LED package 60 that is similar to the LED package 58 of FIG. 16 for embodiments where the alignment features 18-3 and the protrusions 20_{P} of the light collector 20 also have different shapes. As illustrated, the alignment features 18-3 form the shape of half circles similar to FIG. 14, and the protrusions 20_{P} of the light collector 20 are formed in the shape of triangles that fit within the half circles of the alignment features 18-3 for securing the light collector 20 in place.

FIG. 18 is a top view of an LED package 62 that is similar to the LED package 56 of FIG. 15 for embodiments where the alignment features 18-4 are formed with circular shapes or dots as described above for FIG. 14. As illustrated, the alignment features 18-4 form the shape of circles from the top view. In certain embodiments, the alignment features 18-4 may form bore holes in which the protrusions 20_{P} of the light collector 20 reside as illustrated in FIG. 13.

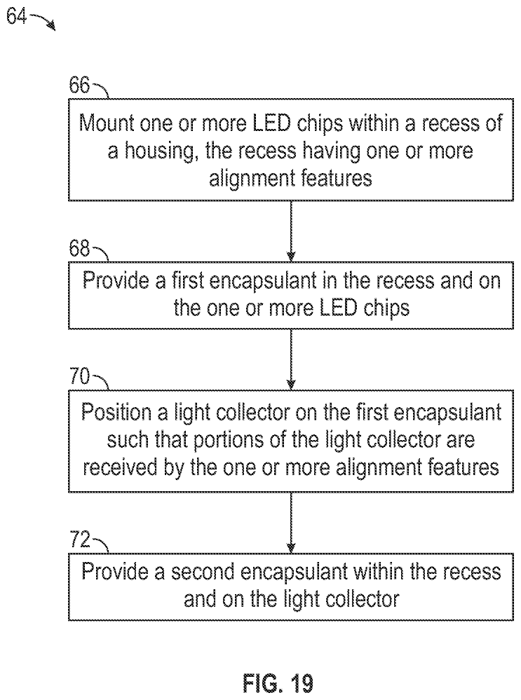

FIG. 19 is a schematic process flow representing a method of manufacturing LED packages according to principles of the present disclosure. The schematic process flow may be implemented to make any of the previous embodiments of FIGS. 1A to 18. Particular fabrication details may be found in the description of FIG. 12, and the following description of FIG. 19 is provided with numberings in reference to the example of FIG. 12. In a first step 66, one or more LED chips 12 are mounted within the recess 16_{R} of the housing 16. As described above, the recess 16_{R} may comprise one or more sidewalls with one or more alignment features 18. In a second step 68, the first encapsulant 50 is filled within the recess 16_{R} to cover the one or more LED chips 12. The first encapsulant 50 may be filled up or even over the alignment features 18. In a third step 70, the light collector 20 is positioned on the first encapsulant 50 such that portions or protrusions 20_{P} (e.g., FIG. 5E) of the light collector 20 are received by the one or more alignment features 18. In a fourth step 72, the second encapsulant 52 is provided within the recess and on the light collector 20. In certain embodiments, the first encapsulant 50 may be partially or fully cured after the light collector 20 is in place, and the second encapsulant 52 is cured thereafter. In certain embodiments, the first encapsulant 50 is filled to a level that reduces or prevents air bubbles. In other embodiments, the first encapsulant 50 may be filled to a level the forms an upper surface with a downward meniscus below the light collector 20. In such embodiments, portions of the second encapsulant 52 may then also fill the areas between the light collector 20 and the first encapsulant 50.

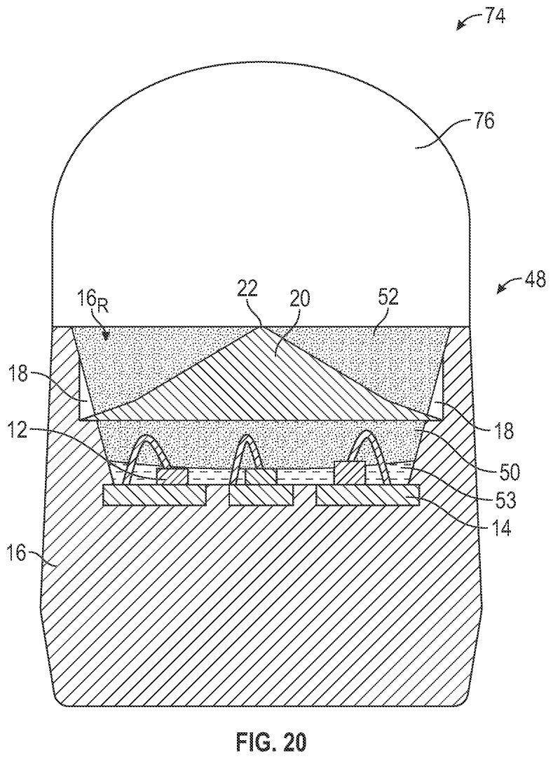

FIG. 20 is a cross-section of an LED package 74 that is similar to the LED package 48 of FIG. 12 with the addition of a lens 76. The lens 76 is positioned on the housing 16 and over the recess 16_{R} to shape an emission pattern (e.g., a far field pattern) of light exiting the LED package 74. The lens 76 may comprise various light-transmissive and/or light-transparent materials, such as silicone, epoxy, or glass, among others. The light collector 20 is positioned between the lens 76 and the LED chips 12. In this manner, the light collector 20 is positioned to receive light from the LED chips 12 and deliver the light into the lens 76 with increased uniformity.

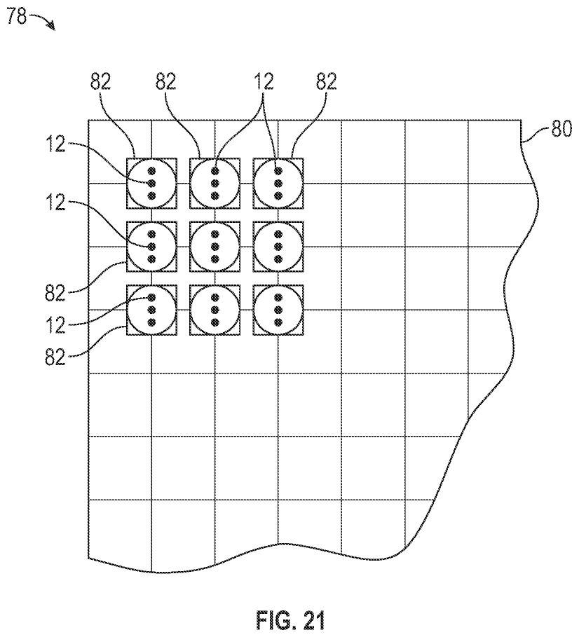

FIG. 21 is a schematic diagram of a portion of an LED display screen 78, for example, an indoor and/or outdoor screen comprising, in general terms, a display panel including a driver printed circuit board (PCB) 80 carrying a large number of surface-mount devices (SMDs) 82 arranged in rows and columns, each SMD 82 defining a pixel. The SMDs 82 may comprise LED packages with LED chips 12 as described above for any of the embodiments shown in FIGS. 1A-20. The SMDs 82 are electrically connected to traces or pads on the PCB 80 to respond to appropriate electrical signal processing and driver circuitry (not shown). As disclosed above, it is to be appreciated that while FIG. 21 depicts the LED chips 12 in a linear arrangement, in other embodiments, the LED chips 12 may be arranged in different configurations.

For any of the previously described embodiments, alignment features 18 and/or adhesion features 28 may be formed with relative dimensions for improving alignment and adhesion while occupying reduced area of housings 16. For example, a lateral dimension of the alignment feature 18 may be measured in a direction parallel from the floor of the recess 16_{R} along a cross-section of an LED package as shown in any of FIGS. 1E/1F, 2E/2F, 3E/3F, 4E/4F, 5E/5F, 6E/6F, 7B/7C, 8E/8F, 9E/9F, 10E/10F, 11E/11F, 12-18, and 20. A ratio of the lateral dimension of the alignment feature 18 to a distance as measured from an edge of the alignment feature 18 closest to the LED chip 12 to an outer wall of the housing 16 closest to the alignment feature 18 may be less than 0.6, or less than 0.5, or less than 0.4, or less than 0.25 in various embodiments.

In a similar manner, a lateral dimension of the adhesion feature 28 may be measured in a direction parallel from the floor of the recess 16_{R} along a cross-section of an LED package as shown in any of FIGS. 4E/4F, 6E/6F, 7B/7C, 9E/9F, and 11E/11F. A ratio of the lateral dimension of the adhesion feature 28 to the lateral dimension of the corresponding alignment feature 18 where the adhesion feature 28 is formed may be less than 0.5, or less than 0.3, or less than 0.2 in various embodiments.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
one or more LED chips;
a light collector arranged over the one or more LED chips; and
at least one alignment feature configured to receive a portion of the light collector.

2. The LED package of claim 1, further comprising a housing, wherein the housing forms a recess with a recess floor and one or more recess sidewalls, and wherein the at least one alignment feature is formed in the one or more recess sidewalls.

3. The LED package of claim 2, wherein the at least one alignment feature comprises one or more of a notch, an indentation, a bore hole, a channel, a groove, and a dot in the one or more recess sidewalls.

4. The LED package of claim 2, wherein the at least one alignment feature comprises a horizontal lip parallel to the recess floor and along the one or more recess sidewalls.

5. The LED package of claim 4, wherein a ratio of a lateral dimension of the at least one alignment feature parallel to the recess floor to a distance from an outer wall of the housing to an edge of the at least one alignment feature closest to the one or more LED chips is less than 0.6.

6. The LED package of claim 4, further comprising an adhesion feature within the horizontal lip.

7. The LED package of claim 6, wherein:
a ratio of a lateral dimension of the at least one alignment feature parallel to the recess floor to a distance from an outer wall of the housing to an edge of the at least one alignment feature closest to the one or more LED chips is less than 0.6; and
a ratio of the lateral dimension of the at least one alignment feature to a lateral dimension of the adhesion feature in a direction parallel to the recess floor is less than 0.5.

8. The LED package of claim 6, wherein the at least one alignment feature and the adhesion feature continuously extend around an entire perimeter of the recess.

9. The LED package of claim 4, further comprising a segmented adhesion feature within the horizontal lip.

10. The LED package of claim 2, wherein the at least one alignment feature comprises a cutout shape in the one or more recess sidewalls, the cutout shape configured to receive a corresponding protrusion of the light collector.

11. The LED package of claim 10, further comprising an adhesion feature within the cutout shape.

12. The LED package of claim 2, wherein the at least one alignment feature comprises two alignment features on opposing sides of the one or more LED chips.

13. The LED package of claim 2, further comprising a lead frame structure at least partially within the housing, wherein the one or more LED chips are electrically coupled to one or more anode leads and one or more cathode leads of the lead frame structure.

14. The LED package of claim 13, wherein portions of the one or more anode leads and portions of the one or more cathode leads extend out of the housing and bend along a bottom surface of the housing.

15. The LED package of claim 2, further comprising an underfill material on the recess floor and adjacent to the one or more LED chips.

16. The LED package of claim 15, further comprising:
a first encapsulant layer on the underfill material, wherein the first encapsulant layer is between the light collector and the underfill material; and
a second encapsulant layer on the light collector, wherein the light collector is between the first encapsulant layer and the second encapsulant layer.

17. The LED package of claim 1, further comprising a lens, wherein the light collector is between the lens and the one or more LED chips.

18. A method for making a light-emitting diode (LED) package, the method comprising:
mounting one or more LED chips within a recess of a housing, the recess comprising a recess floor and one or more recess sidewalls with one or more alignment features;
providing a first encapsulant within the recess and on the one or more LED chips;
positioning a light collector on the first encapsulant such that portions of the light collector are received by the one or more alignment features; and
providing a second encapsulant within the recess and on the light collector.

19. The method of claim 18, further comprising at least partially curing the first encapsulant after providing the light collector and before providing the second encapsulant.

20. The method of claim 19, further comprising curing the second encapsulant.

21. The method of claim 18, wherein the second encapsulant comprises at least one of a light-reflective material and a light-absorbing material.

22. The method of claim 18, wherein the first encapsulant is provided within the recess and at least up to the one or more alignment features.

23. The method of claim 18, wherein the one or more alignment features comprise one or more of a notch, an indentation, a bore hole, a channel, a groove, and a dot in the one or more recess sidewalls.

24. The method of claim 18, wherein the one or more alignment features comprise a horizontal lip parallel to the recess floor and along the one or more recess sidewalls.

25. The method of claim 24, further comprising an adhesion feature within the horizontal lip.

26. The method of claim 25, wherein the adhesion feature is segmented within the horizontal lip.

27. The method of claim 25, wherein the one or more alignment features and the adhesion feature continuously extend around an entire perimeter of the recess.

28. The method of claim 18, wherein the one or more alignment features comprise a cutout shape in the one or more recess sidewalls, the cutout shape configured to receive a corresponding protrusion of the light collector.

29. The method of claim 18, further comprising providing an underfill material within the recess before providing the first encapsulant.

30. A light-emitting diode (LED) display comprising:
a display panel; and
at least one LED package comprising:
one or more LED chips;
a light collector arranged over the one or more LED chips; and
at least one alignment feature configured to receive a portion of the light collector.
